(19) United States
(12) Patent Application Publication
(10) Pub. No.: US 2024/0378409 A1
(43) Pub. Date: Nov. 14, 2024

(54) DOCUMENT WITH ANTENNA OF DUAL SHIELDING/COMMUNICATION FUNCTION

(71) Applicant: LINXENS HOLDING, Mantes la Jolie (FR)

(72) Inventors: Somchard PHANNAM, Phra Nakhon Si Ayutthaya (TH); Kachen CHANTHET, Phra Nakhon Si Ayutthaya (TH); Khiengkrai KHUSUWAN, Phra Nakhon Si Ayutthaya (TH); Arporn SUNGKHAPUN, Phra Nakhon Si Ayutthaya (TH)

(21) Appl. No.: 18/691,756

(22) PCT Filed: Oct. 28, 2021
(86) PCT No.: PCT/IB2021/000747

§ 371 Date: Mar. 13, 2024

(51) Int. Cl. G06K 19/07; G06K 19/073; G06K 19/077

(52) U.S. Cl. CPC G06K 19/0726; G06K 19/07309; G06K 19/0779

(57) ABSTRACT

In an aspect, the present invention provides a document having a first page and a second page connected by a hinge portion. In illustrative embodiments, the document comprises an RF chip module, a first antenna portion formed on the first page, a second antenna portion formed on the second page, and at least one foldable bridge formed on the hinge portion, wherein the at least one foldable bridge electrically connects endings of the first and second antenna portions such that the first and second antenna portions have a first inductance adapted to provide the document with a first resonance frequency in a closed condition of the document in which the first page is placed on the second page, while the first and second antenna portions have a second inductance adapted to provide the document with a second resonance frequency different from the first resonance frequency in an open condition of the document in which the first page is removed from closed condition.

### RELATED APPLICATION

This application is a 35 U.S.C. § 371 application of and claims priority from PCT Application Serial No. PCT/IB2021/000747, entitled “Document with Antenna of Dual Shielding/Communication Function,” filed on Oct. 28, 2021, the contents of which are hereby incorporated herein in their entirety by this reference.

### FIELD OF THE INVENTION

The present invention relates to a document with an antenna having a dual function of shielding and RF communication. In particular, the invention relates to a document having an antenna that is used for shielding an RF chip module of the document, but allows communication with the RF chip module when a user of the document permits the communication.

### BACKGROUND ART

Increasingly, security documents of the identity document type, such as identity document booklets (e.g., passports), identity cards, and the like, include an electronic circuit with contactless reading. The electronic circuit comprises an electronic module or chip connected to an inductive or capacitive antenna. This type of device can be used, for example, to store personal data concerning civil status and biometric data, as well as administrative data in digital form.

When security documents are to be checked for verifying its validity or electronically reading information provided by such a document, the stored data is read by a receiving device or reader by means of a remote electronic coupling between the electronic circuit of a security document, often referred to as a transponder, and the reader. The use of contactless technologies provides significant advantages in lifetime and ergonomic terms. However, it is important to ensure that an unintended reading of the identity document cannot take place, particularly, that the security document is not read without the knowledge of the holder of the security document. In practice, a contactless technology in security documents may be more acceptable when the authorization to read data stored in the document remains under the control of the document holder.

An existing solution is the use of a passive element for masking the antenna of the security document, such as in terms of an electromagnetic shielding bag. In practice, the security document to be protected from unintentional reading is placed in the electromagnetic shielding bag and only removed from the electromagnetic shielding bag when the holder of the security document intends to present the security document to a reading device.

In fact, the usage of a passive element for masking the antenna, such as an electromagnetic shielding bag, requires the additional task of removing the security document from the shielding bag when presenting the security document. This additional task may impose a significant inconvenience for the holder of the security document and, therefore, may be considered as a suboptimal solution, especially in the mass market where users frequently forego such inconveniences.

Document US 2007/0164866A1 shows a security document having a contactless chip with data masking. The security document comprises a transponder of an electronic module connected to an antenna placed on a given surface of a first part of the document, wherein the transponder serves to remotely communicate with a reader via an electromagnetic coupling. Furthermore, the security document comprises a passive masking element for the antenna, wherein the passive masking element is supported by a second part of the document and can move relative to the first part. The masking element is capable of interfering with the coupling between the transponder and the reader for rendering the reading of the document impossible when the second part is in a predetermined position that corresponds to a closed position of the document.

In view of the above-discussed background art, it is desirable to provide a document with an improved shielding function that ensures that only an authorized reader may read the document and inhibits unintended reading by others than the authorized reader when allowing the authorized reader to read the document.

### SUMMARY

The above-indicated problems and objects are solved by a document as defined in independent claim 1. More advantageous embodiments are defined in the dependent claims 2 to 12.

In various aspects and embodiments of the present invention, a document having an RF chip module is provided, the RF chip module being electrically connected with an antenna integrated into the document.

In an aspect, the present invention provides a document having a first page and a second page connected by a hinge portion. In illustrative embodiments, the document comprises an RF chip module, a first antenna portion formed on the first page, a second antenna portion formed on the second page, and at least one foldable bridge crossing the hinge portion, e.g. formed over or formed within the hinge portion, so as to electrically connect endings of the first and second antenna portions with each other such that the first and second antenna portions have a first inductance adapted to provide the document with a first resonance frequency in a closed condition of the document in which the first page is placed on the second page, while the first and second antenna portions have a second inductance adapted to provide the document with a second resonance frequency different from the first resonance frequency in an open condition of the document in which the first page is not placed on the second page. Accordingly, the different resonance frequency associated with the different conditions of the document (i.e., open and closed document) allow a selective reading of the document in one condition, while blocks a reading in the other condition. That is, upon matching the second resonance frequency with a resonance frequency of a reading device, reading of the document may be enabled in the open condition, while blocking reading of the document in the closed condition because of a mismatch between the first resonance frequency and the second resonance frequency. For example, the first resonance frequency may be detuned compared to an external ISO 14443 reader. In some illustrative examples herein, the first and second antenna portions may be formed by planar coil winding sections corresponding to sections of planar air core coils. Accordingly, the first and second antenna portions, being connected with the foldable bridge(s), provide an antenna integrated in to the document.

The hinge portion allows the document to be closed by arranging the first and second pages in a stacked arrangement, while the document may be open when unfolding the stacked arrangement of the first and second pages. For example, each of the first and second pages may be connected to the hinge portion via a fold, the folds being arranged substantially in parallel.

In some illustrative embodiments of this aspect, the first and second antenna portions may be formed with equal winding orientation in the open condition and with opposite winding orientation in the closed condition. Accordingly, the first and second antenna portions function as a shielding in the closed condition of the document because the currents induced in the first and second antenna portions suppress each other due to the inverse orientation of the first and second winding orientations. For example, a degree of suppression of the induced currents in the closed condition of the document depends on a degree of similarity of the first and second antenna portions. This means that, for the first and second antenna portions being provided by coil winding sections of equal winding number, an improved suppression is achieved in comparison to the coil winding sections having unequal winding numbers. It may thus be ensured in the closed condition of the document that unintended reading of the document is inhibited. By contrast, when opening the document such that the first and second pages are separated from each other, i.e., not in a stacked arrangement as in the closed condition, and exposed to an authorized reader, the first and second antenna portions combine to function as communication antennas, allowing the authorized reader to read the document because in the open condition the first and second winding orientations are substantially of same chirality (means that vectors associated with the winding orientations according to a curl right hand rule, do not have any component along opposite directions). In the open condition of the document, the first and second pages may be arranged next to each other such that an angle formed by the first and second pages may be substantially greater than 10°, preferably greater 45° or greater than 90° or greater than 120°, more preferably greater than 150° degrees and smaller than 250° or smaller than 220°. In other words, the first and second antenna portions each function in the open condition of the document as a unique antenna, while the first and second antenna portions provide a shielding function in the closed condition of the document. Therefore, the first and second antenna portions may be exposed to an authorized reader in the open condition for allowing the authorized reader to communicate with the RF chip module via the first and second antenna portions, while the document in the closed condition does not allow unintended communication with the RF chip module in a reliable and easy manner.

In some other illustrative embodiments of this aspect, the first and second antenna portions may be formed with opposite winding orientation in the open condition and with equal winding orientation in the closed condition. Accordingly, the different winding orientations in the open and closed conditions allow to realize different inductances and, thus, resonance frequencies in the open and closed conditions. That is, a shift in the resonance frequencies from the closed condition to the open condition and vice versa may be easily achieved such that a shielding function may be implemented when matching the second resonance frequency to the resonance frequency of an external reader, while shifting the first resonance frequency to deviate from the second resonance frequency in the closed condition.

In some illustrative embodiments of this aspect, the foldable bridge may be formed by two flexible strip portions of electrically conductive material, each flexible strip portion extending across a fold of the hinge portion. The fold may represent a fold along which the document is unfolded when opening the document. Accordingly, a simple but reliable electrical connection between the first and second antenna portions may be provided that is not impaired by repeatedly closing and opening the document. For example, each flexible strip portion may be attached to the first and second pages via attachment points provided in the first and second pages. Accordingly, a mechanical load acting on the flexible strips is reduced and only acts at the attachment points where a punctual reinforcement may ensure that the foldable bridge is not affected by repeatedly closing and opening the document. In some special illustrative but non-limiting examples, the attachment of the foldable bridge may be achieved via crimping, gluing, and the like. In additional or alternative examples of these illustrative embodiments, each flexible strip portion may be attached to wire end portions of the first and second antenna portions via bonding connections, e.g., thermocompression (TC) bonding connections. In special illustrative examples of TC bonding, the antenna portions and the flexible strips may be formed of any of gold, silver or copper materials and a very reliable diffusion bond may be provided.

In some illustrative embodiments of this aspect, the first and second antenna portions may be arranged in the first and second pages so as to superimpose in the closed condition. Accordingly, a shielding effect of the first and second antenna portions in the closed condition may be improved. In some special illustrative embodiments herein, the first and second antenna portions may have equal size and shape. In this case, an advantageous shielding function may be very reliably achieved.

In some exemplary embodiments, the RF chip module may comprise an integrated circuit chip with contact terminals, the contact terminals being physically connected to ends of one of the first and second antenna portions by means of connection methods such as TC bonding, soldering, crimping, use of conductive adhesive etc. This may be an advantageous implementation of a secure document with such an integrated circuit chip. In some special but non-limiting example herein, the first antenna portion may be formed by two antenna coil sections, wherein the ends of each of the two antenna coil sections may be connected with a respective one of the contact terminals and with the at least one foldable bridge. For example, a winding number of the first and second antenna portions may be equal.

In some illustrative embodiments of this aspect, the RF chip module may be integrated into one of the first page and the second page. Accordingly, the RF chip module may be protected against damage caused by opening and closing the document.

In some illustrative embodiments of this aspect, the first and second antenna portions may each comprise a conductive material, e.g. aluminum and/or copper and/or silver and/or metal alloy material and/or a conductive foil laminated with an insulated layer and/or a wire and/or a conductive ink, which represent an advantageous conductive material to be used as shielding material and absorber. Accordingly, an advantageous shielding or antenna may be realized depending whether the document is open or closed. For example, the first and second antenna portions may be formed by at least one of an etched metallic foil disposed over the first and/or second page or a metallic ink printed onto the first and/or second page or a wire embedded into the material of the first and/or second page. Accordingly, the first and second antenna portions may be easily formed in an accurate manner. For example, the first and second antenna portions may have a thickness of at most 100 μm such that the first and second antenna portions may be fabricated at low cost without creating an uneven surface of the document due to an extensive stepping in the surface of the document.

In some illustrative embodiments of this aspect, the document may be a booklet having a booklet cover formed by the first and second pages and one or more additional pages connected to the hinge portion, the one or more pages being enclosed by the booklet cover. Accordingly, the document may be advantageously provided as a booklet, such as an identity booklet, e.g., a passport, having advantageous shielding protection against unintended reading when the document is in a closed condition.

### BRIEF DESCRIPTION OF THE DRAWINGS

The present invention will be explained in greater detail with regard to the accompanying drawings in which:

FIG. 1 schematically illustrates, in a top view, a document in accordance with some illustrative embodiments of the present invention in an open condition of the document;

FIG. 2a schematically illustrates, in a top view, a winding orientation in the document shown in FIG. 1;

FIG. 2b schematically illustrates, in a top view, a winding orientation in the document of FIG. 1 shown in a closed condition; and

FIG. 3 schematically illustrates, in a top view, a document in accordance with some other illustrative embodiments of the present invention in an open condition of the document.

### DETAILED DESCRIPTION

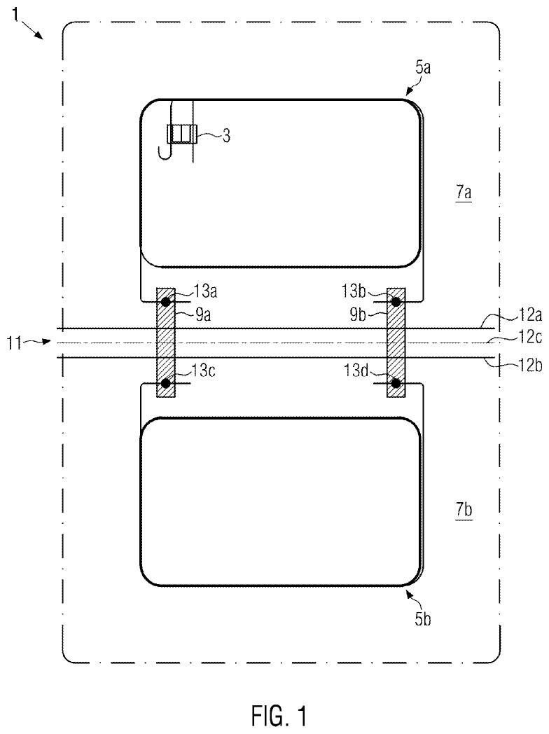

Referring to FIG. 1, a document 1 is shown. The document 1 comprises a chip module 3, a first antenna portion 5a formed on a first page 7a of the document 1, a second antenna portion 5b formed on a second page 7b of the document 1, and foldable bridges 9a, 9b formed over a hinge portion 11 of the document 1. In FIG. 1, the document 1 is shown in an open condition and the hinge portion 11 allows the document 1 to be closed by arranging the first page 7a and the second page 7b in a stacked arrangement such that the document 1 may be in a closed condition (not illustrated in FIG. 1). In other words, the document 1 may be open when unfolding the stacked arrangement of the first page 7a and second page 7b of the closed condition (not illustrated in FIG. 1). For example, the first page 7a and the second page 7b may be connected to the hinge portion 11 via a respective one of folds 12a and 12b or the hinge portion 11 may be rigidly formed with the first and second pages 7a and 7b and the document 1 may be folded along a fold indicated by line 12c in FIG. 1. As shown in FIG. 1, the folds 12a and 12b are substantially in parallel.

Although two foldable bridges 9a and 9b are shown, this does not impose any limitation onto the present disclosure and one foldable bridge (not illustrated) or more than three foldable bridges (not illustrated) may be provided. At least one of the foldable bridges 9a and 9b may be formed by a flexible strip portion of an electrically conductive material. The flexible strip portion may extend across the folds 12a and 12b and/or the fold 12c of the hinge portion 11 as shown in FIG. 1.

In accordance with some illustrative embodiments, the foldable bridges 9a and 9b are attached to the first page 7a and the second page 7b via attachment points 13a to 13d provided in the first page 7a and the second page 7b. For example, the attachment of the foldable bridges 9a and 9b may be achieved via crimping, gluing, and the like. This attachment may mechanically attach the foldable bridges 9a and 9b to the pages 7a and 7b, as well as electrically connect the foldable bridges 9a and 9b to ends of the first and second antenna portions 5a and 5b.

According to illustrative embodiments, the first antenna portion 5a and second antenna portion 5b may be provided by planar air core coils. This does not limit the present disclosure by any means and a planar coil embedded into the pages 7a and 7b such that a planar coil without air core may be provided. A core may be provided by the material of the page(s) 7a, 7b or by a magnetic core which is provided on and/or within the page(s) 7a, 7b.

In accordance with some illustrative examples, the first and second pages 7a and 7b may comprise at least one of a piece of paper, a piece of cardboard, a piece of paperboard, a piece of millboard, a piece of pasteboard, a piece of corrugated fiberboard, a board of polycarbonate material and a paper-based material and a synthetic fiber paper and/or the like. For example, synthetic fiber paper may be understood as representing a non-cellulosic sheet material resembling paper and used in a similar fashion, typically made from thermoplastic materials such as polyolefins, nylon, polystyrene, etc., by direct film or foil extrusion or by bonding filaments thereof. Additionally or alternatively, synthetic fiber paper is understood as representing a category of paper that is made without any wood fibers and is especially formulated to be receptive to commercial printing inks. In any way, synthetic fiber paper differs from a plastic film with respect to printing characteristics and it differs from traditional paper due to the lack of wood fibers. In other words, synthetic fiber paper is considered as being a paper-like film that lies somewhere between traditional plastic films and high-value paper. As opposed to traditional paper, synthetic fiber papers use a plastic resin backbone rather than the pulped wood fibers used in traditional paper. However, synthetic fiber papers and traditional papers both use mineral fillers and optical brighteners to gain opacity, brightness and smoothness. Therefore, printability characteristics for synthetic fiber papers and traditional papers formed of a wood pulp are comparably developed by the use of calendaring rolls and imparting surface printability enhancements.

In accordance with some illustrative examples, each of the first page 7a and the second page 7b may be a continuous sheet of material. For example, each of the first page 7a and the second page 7b may be a continuous sheet of material having substantially a homogeneous thickness and/or a homogeneous stiffness. The expression “homogeneous stiffness” means that each of the first page 7a and the second page 7b may not be folded without permanently deforming each of the first page 7a and the second page 7b. In this case, each of the first page 7a and the second page 7b may be a card interconnected by the hinge portion 11.

In accordance with some special illustrative examples, each of the first page 7a and the second page 7b may be provided by a synthetic fiber paper material as described above. In this case, it is possible to attach a thin metallic foil on the first and second pages 7a and 7b in a comparatively smooth manner when compared to a case in which the first and second pages 7a and 7b comprise traditional paper material where a thin metallic foil attached to the first and second pages 7a and 7b is creased, thereby impairing bonding of subsequent layers on the pages 7a and 7b and/or on the antenna portions 5a and 5b and/or the chip module 3.

In accordance with some illustrative examples, each of the antenna portions 5a and 5b may have a thickness of at most 100 μm. For example, the thickness of the antenna portions 5a and 5b may be in the range from about 1 μm to about 100 μm. The person skilled in the art will appreciate that the upper limit of 100 μm for the thickness of the antenna portions 5a and 5b may not be considered as limiting the invention to this thickness. However, in addition to aesthetic reasons according to which it may be desirable to reduce an amount of possible stepping in the document's surface due to the presence of the antenna portions 5a and 5b, it is cost efficient and allows to saves resources when optimizing the thickness of the antenna portions 5a, 5b to an thickness range in which a required minimum performance of the antenna is realized, while reducing the amount of materials employed in the preparation and attachment of the antenna portions 5a, 5b over the pages 7a, 7b. For example, aside from reducing the amount of material used for preparing the antenna portions 5a and 5b, an amount of adhesive means used for attaching the antenna portions 5a and 5b over the pages 7a and 7b 11 may be reduced, as well. Furthermore, a risk of unintentional damage of the document 1 due to a stepping of more than 100 μm caused by the antenna portions 5a and 5b formed over the pages 7a and 7b may be reduced. Regarding a lower limit of the thickness of the antenna portions 5a and 5b, a performance of the antenna portions 5a, 5b having a thickness of less than 1 μm may not be sufficiently high to ensure a required performance of the antenna portions 5a, 5b.

Referring to FIG. 1, the first antenna portion 5a may be arranged so as to surround or encircle the chip module 3, both being arranged over the first page 7a. For example, the first page 7a, the first antenna portion 5a and the chip module 3 may be laminated together. Alternatively, the chip module 3 may be arranged at least partially in between the first antenna portion 5a and the first page 7a or the first antenna portion 5a may be arranged between the chip module 3 and the first page 7a.

In accordance with some special illustrative embodiments, each of the first and second antenna portions 5a and 5b may be one of an etched metallic foil, such as a foil made of aluminum, copper and the like, attached to the first page 7a and/or the second page 7b, a metallic ink printed onto the first page 7a and/or the second page 7b, such as a silver ink or paste or a wire embedded into the material of the first page 7a and/or second page 7b. For example, the metallic foil may be attached by means of a heat-activated glue or a cold glue or by means of hot or cold roll lamination techniques. In accordance with some preferred but not limiting examples herein, an aluminum foil may be etched for providing the antenna portions 7a and 7b, the aluminum foil representing a cost efficient material when compared to other materials employed as conductive coatings used for antennas, such as copper and silver.

In accordance with some special advantageous, but not limiting embodiments of the present disclosure, a metallic foil may be provided by forming a thin layer of metal on a carrier material, such as a PET material. For example, as a metal material for the thin layer of metal, aluminum, copper, silver and the like may be used. Furthermore, the accordingly provided metallic foil may have an optional adhesive layer bonded thereon, such that the metallic foil together with the adhesive layer may be attached on the first and second pages 7a and 7b by means of the adhesive layer and, optionally, the carrier material may be removed after attachment of the metallic foil on the pages 7a, 7b, thereby leaving the thin layer of metal on the pages 7a, 7b attached thereto with the adhesive layer. In case that the carrier layer is not removed, the carrier layer may provide an improved bonding strength to subsequently formed layers on the antenna portions 5a and 5b.

With ongoing reference to FIG. 1, the chip module 3 may further include an integrated circuit chip (not illustrated) and a memory device (not illustrated) which may save personal data of the holder of the document 1, such as identity data of the holder, bank data of the holder, security data of the holder. The memory device (not illustrated) may be only readable or may be readable and writable with new information input by the holder of the document 1. The integrated circuit chip (not illustrated) may have contact terminals, which may be physically connected to ends of the first antenna portion 5a by means of connection methods such as TC bonding, soldering, crimping, use of conductive adhesive etc. For example, the first antenna portion 5a may be formed by two antenna coil sections (not illustrated), wherein the ends of each of the two antenna coil sections may be connected with a respective one of the contact terminals and with one of the foldable bridges 9a, 9b. Alternatively, the RF chip module 3 may be inductively and/or capacitively coupled to one of the antenna portions 5a and 5b.

In some illustrative embodiments herein, a winding number of the first and second antenna portions 9a and 9b may be equal.

As described above, the hinge portion 11 of the document 1 may be folded such that the first page 7a may be folded onto the second page 7b or vice versa. In some illustrative embodiments herein, the first and second antenna portions 5a and 5b may be arranged in the first and second pages 7a and 7b so as to superimpose in the closed condition of the document 1. For example, the first and second antenna portions 5a and 5b may have equal size and shape and folding the first page 7a and the second page 7b into a stacked arrangement brings the first antenna portion 5a and the second antenna portion 5b into a congruent superimposition.

In accordance with some illustrative embodiments and with ongoing reference to FIG. 1, document 1 may be a booklet. In this case, the first and second pages 7a and 7b may correspond to a booklet cover of the booklet. The booklet may comprise one or more additional pages (not illustrated) connected to the hinge portion 11, the one or more pages (not illustrated) being enclosed by the booklet cover.

Referring to FIG. 1, the first and second antenna portions 5a, 5b of the document 1 have a first inductance adapted to provide the document 1 with a first resonance frequency in the closed condition of the document 1 in which the first page 7a is placed on the second page 7b, while the first and second antenna portions 5a, 5b have a second inductance adapted to provide the document 1 with a second resonance frequency different from the first resonance frequency in the open condition of the document in which the first page is removed from the closed condition. In some illustrative embodiments herein, the first and second antenna portions 5a, 5b may be formed with equal winding orientation in the open condition and with opposite winding orientation in the closed condition, while in some other illustrative embodiments, the first and second antenna portions 5a, 5b may be formed with opposite winding orientation in the open condition and with equal winding orientation in the closed condition. In any of these illustrative embodiments, the second resonance frequency may be matched with the resonance frequency of an external reader (not illustrated), while the first resonance frequency may be detuned from the second resonance frequency such that an external reader (not illustrated) is not able to communicate with the chip module 3 of the document 1 in the closed condition. For example, the second resonance frequency may be in a range from about 10 MHz to about 15 MHz, preferably in a range from about 11 MHz to about 14 MHz, such as about 13.5 MHz. The first resonance frequency may deviate from the second resonance frequency by at least 5% or at least 10% or at least 20% of the second resonance frequency. For example, the first resonance frequency may be greater than 14 MHz or greater than 15 MHz or greater than 19 MHz, e.g., in a range from about 19 MHz to about 21 MHz.

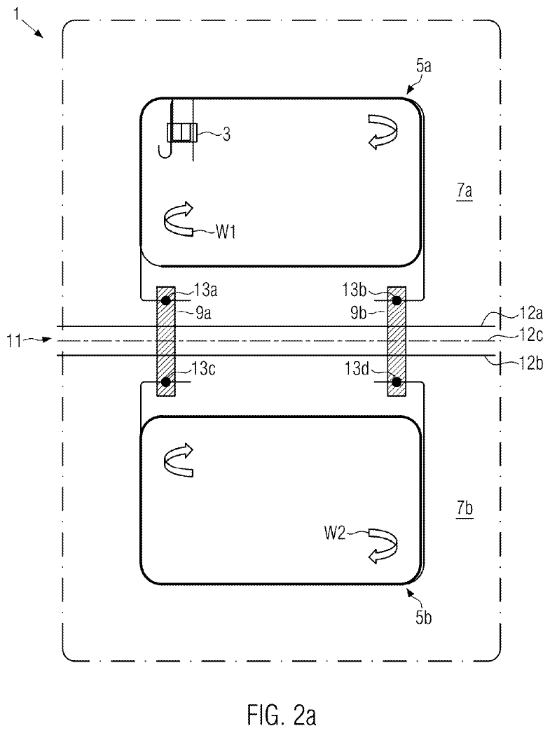

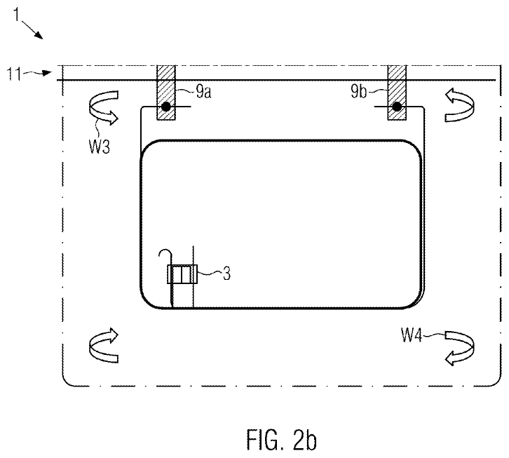

Referring to FIGS. 2a and 2b, an open condition of the document 1 as described above with regard to FIG. 1 is shown in FIG. 2a, while FIG. 2b shows the document 1 in closed condition.

With reference to FIG. 2a, the antenna portions 5a and 5b are arranged such that a winding orientation of the antenna portions 5a and 5b is equal as indicated by arrows W1 and W2 which schematically depict a winding orientation of the first antenna portion 5a by arrow W1 and a winding orientation of the second antenna portion 5b by arrow W2. Accordingly, each of the first antenna portion 5a and the second antenna portion 5b may be used for reading the chip of the chip module 3 when exposing at least one of the first antenna portion 5a and the second antenna portion 5b to a reading device (not illustrated). That is, a reading of document 1 in the open condition is possible when the reading device (not illustrated) couples to at least one of the first antenna portion 5a and the second antenna portion 5b, thereby increasing a surface area at which a reading of document 1 is possible.

Referring to FIG. 2b, the document 1 is shown in closed condition in which the first and second pages 7a and 7b are in a stacked arrangement. In the closed condition, winding orientations of the antenna portions 5a and 5b are in opposite directions. In particular, arrow W3 indicating a winding orientation of the first antenna portion 5a is oriented in an opposite direction as a winding orientation of the second antenna portion 5b which is illustrated by arrow W4. Accordingly, the first antenna portion 5a and the second antenna portion 5b in combination shield each other against unintended reading of the chip of the chip module 3 in case that the document 1 is exposed to a reading device (not illustrated).

Although FIGS. 2a and 2b schematically illustrate a special illustrative example of the document 1 in which the winding orientations of the first and second antenna portions 5a and 5b are opposite to each other, this does not pose any limitation onto the present disclosure and the first and second antenna portions 5a and 5b may be formed so as to have equal winding orientation in the open and closed conditions. For example, the orientation of the arrows W1 and W3 may be inversed to match the orientation of the arrows W2 and W4 or the orientation of the arrows W2 and W4 may be inversed to match the orientation of the arrows W1 and W3.

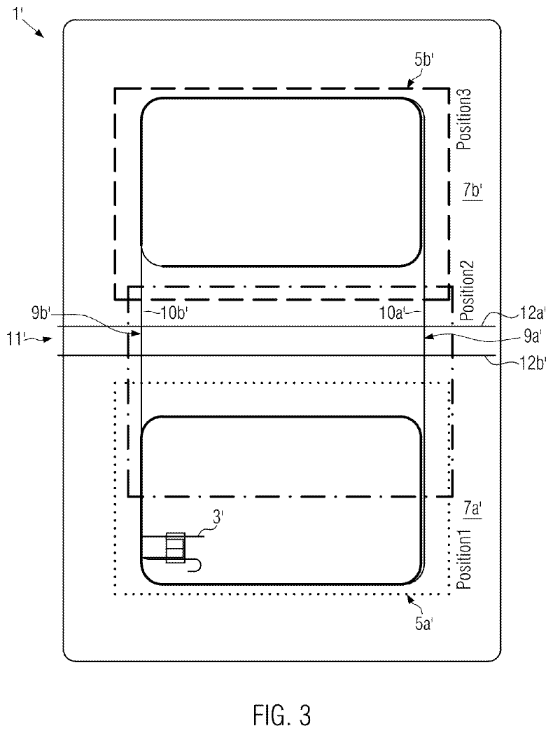

In accordance with some other illustrative embodiments, FIG. 3 shows a document 1′ comprising a chip module 3′, a first antenna portion 5a′ formed on a first page 7a′ of the document 1′, a second antenna portion 5b′ formed on a second page 7b′ of the document 1, and foldable bridges 9a′, 9b′ crossing a hinge portion 11′ of the document 1′.

In FIG. 3, the document 1′ is shown in an open condition and the hinge portion 11′ allows the document 1′ to be closed by arranging the first page 7a′ and the second page 7b′ in a stacked arrangement such that the document 1′ may be in a closed condition (not illustrated in FIG. 1). In other words, the document 1′ may be open when unfolding the stacked arrangement of the first page 7a′ and second page 7b′ of the closed condition (not illustrated in FIG. 3). For example, the first page 7a′ and the second page 7b′ may be connected to the hinge portion 11′ via a respective one of folds 12a′ and 12b′ or the hinge portion 11′ may be rigidly formed with the first and second pages 7a′ and 7b′. As shown in FIG. 3, the folds 12a′ and 12b′ may be substantially parallel.

Although two foldable bridges 9a′ and 9b′ are shown in FIG. 3, this does not impose any limitation onto the present disclosure and one foldable bridge (not illustrated) or more than three foldable bridges (not illustrated) may be provided. At least one of the foldable bridges 9a′ and 9b′ may be formed by a wire end portion 10a′ of the first antenna portion 5a′ or by a wire end portion 10b′ of the second antenna portion 10b′. The flexible wire end portions 10a′ and 10b′ may extend across the folds 12a′ and 12b′ of the hinge portion 11′ as shown in FIG. 3. For example, at least one of the wire end portions 10a′ and 10b′ may be embedded into the hinge portion 11′. Additionally or alternatively, at least one of the wire end portions 10a′ and 10b′ may be formed over the hinge portion 11′. In accordance with some illustrative examples herein, the foldable bridges 9a′ and 9b′ may be attached to the first page 7a′ and the second page 7b′ via attachment points (not illustrated) provided in the first page 7a′ and the second page 7b′. For example, the attachment of the foldable bridges 9a′ and 9b′ may be achieved via gluing and the like. This attachment may mechanically attach the foldable bridges 9a′ and 9b′ to the pages 7a′ and 7b′, as well as electrically connect the first and second antenna portions 5a′ and 5b′ with each other. According to some special illustrative example, the first and second antenna portions 5a′, 5b′ and the foldable bridges 9a′, 9b′ may be formed of a single piece of an electric conductive material, e.g., a single wire, such that no electrical connection point needs to be formed between the first and second antenna portions 5a′ and 5b′.

According to some illustrative embodiments, the first antenna portion 5a′ and the second antenna portion 5b′ may be provided by planar air core coils. This does not limit the present disclosure by any means and a planar coil embedded into the pages 7a′ and 7b′ such that a planar coil without air core may be provided. A core may be provided by the material of the page(s) 7a′, 7b′ or by a magnetic core which is provided on and/or within the page(s) 7a′, 7b′.

In accordance with some illustrative examples, the first and second pages 7a′ and 7b′ may comprise at least one of a piece of paper, a piece of cardboard, a piece of paperboard, a piece of millboard, a piece of pasteboard, a piece of corrugated fiberboard, a board of polycarbonate material and a paper-based material and a synthetic fiber paper and/or the like. For example, synthetic fiber paper may be understood as representing a non-cellulosic sheet material resembling paper and used in a similar fashion, typically made from thermoplastic materials such as polyolefins, nylon, polystyrene, etc., by direct film or foil extrusion or by bonding filaments thereof. Additionally or alternatively, synthetic fiber paper is understood as representing a category of paper that is made without any wood fibers and is especially formulated to be receptive to commercial printing inks. In any way, synthetic fiber paper differs from a plastic film with respect to printing characteristics and it differs from traditional paper due to the lack of wood fibers. In other words, synthetic fiber paper is considered as being a paper-like film that lies somewhere between traditional plastic films and high-value paper. As opposed to traditional paper, synthetic fiber papers use a plastic resin backbone rather than the pulped wood fibers used in traditional paper. However, synthetic fiber papers and traditional papers both use mineral fillers and optical brighteners to gain opacity, brightness and smoothness. Therefore, printability characteristics for synthetic fiber papers and traditional papers formed of a wood pulp are comparably developed by the use of calendaring rolls and imparting surface printability enhancements.

In accordance with some illustrative examples, each of the first page 7a′ and the second page 7b′ may be a continuous sheet of material. For example, each of the first page 7a′ and the second page 7b′ may be a continuous sheet of material having substantially a homogeneous thickness and/or a homogeneous stiffness. The expression “homogeneous stiffness” means that each of the first page 7a′ and the second page 7b′ may not be folded without permanently deforming each of the first page 7a′ and the second page 7b′. In this case, each of the first page 7a′ and the second page 7b′ may be a card interconnected by the hinge portion 11′.

In accordance with some special illustrative examples, each of the first page 7a′ and the second page 7b′ may be provided by a synthetic fiber paper material as described above. In this case, it is possible to attach a thin metallic foil on the first and second pages 7a′ and 7b′ in a comparatively smooth manner when compared to a case in which the first and second pages 7a′ and 7b′ comprise traditional paper material where a thin metallic foil attached to the first and second pages 7a′ and 7b′ is creased, thereby impairing bonding of subsequent layers on the pages 7a′ and 7b′ and/or on the antenna portions 5a′ and 5b′ and/or the chip module 3′.

In accordance with some illustrative examples, each of the antenna portions 5a′ and 5b′ may have a thickness of at most 100 μm. For example, the thickness of the antenna portions 5a′ and 5b′ may be in the range from about 1 μm to about 100 μm. The person skilled in the art will appreciate that the upper limit of 100 μm for the thickness of the antenna portions 5a′ and 5b′ may not be considered as limiting the invention to this thickness. However, in addition to aesthetic reasons according to which it may be desirable to reduce an amount of possible stepping in the document's surface due to the presence of the antenna portions 5a′ and 5b′, it is cost efficient and allows to saves resources when optimizing the thickness of the antenna portions 5a′, 5b′ to an thickness range in which a required minimum performance of the antenna is realized, while reducing the amount of materials employed in the preparation and attachment of the antenna portions 5a′, 5b′ over the pages 7a′, 7b′. For example, aside from reducing the amount of material used for preparing the antenna portions 5a′ and 5b′, an amount of adhesive means used for attaching the antenna portions 5a′ and 5b′ over the pages 7a′ and 7b′ may be reduced, as well. Furthermore, a risk of unintentional damage of the document 1′ due to a stepping of more than 100 μm caused by the antenna portions 5a′ and 5b′ formed over the pages 7a′ and 7b′ may be reduced. Regarding a lower limit of the thickness of the antenna portions 5a′ and 5b′, a performance of the antenna portions 5a′, 5b′ having a thickness of less than 1 μm may not be sufficiently high to ensure a required performance of the antenna portions 5a′, 5b′.

Referring to FIG. 3, the first antenna portion 5a′ may be arranged so as to surround or encircle the chip module 3′, both being arranged over the first page 7a′. For example, the first page 7a′, the first antenna portion 5a′ and the chip module 3′ may be laminated together. Alternatively, the chip module 3′ may be arranged at least partially in between the first antenna portion 5a′ and the first page 7a′ or the first antenna portion 5a′ may be arranged between the chip module 3′ and the first page 7a′.

In accordance with some special illustrative embodiments, each of the first and second antenna portions 5a′ and 5b′ may be one of an etched metallic foil, such as a foil made of aluminum, copper and the like, attached to the first page 7a′ and/or the second page 7b′, a metallic ink printed onto the first page 7a′ and/or the second page 7b′, such as a silver ink or paste or a wire embedded into the material of the first page 7a′ and/or second page 7b′. For example, the metallic foil may be attached by means of a heat-activated glue or a cold glue or by means of hot or cold roll lamination techniques. In accordance with some preferred but not limiting examples herein, an aluminum foil may be etched for providing the antenna portions 7a′ and 7b′, the aluminum foil representing a cost efficient material when compared to other materials employed as conductive coatings used for antennas, such as copper and silver.

In accordance with some special advantageous, but not limiting embodiments of the present disclosure, a metallic foil may be provided by forming a thin layer of metal on a carrier material, such as a PET material. For example, as a metal material for the thin layer of metal, aluminum, copper, silver and the like may be used. Furthermore, the accordingly provided metallic foil may have an optional adhesive layer bonded thereon, such that the metallic foil together with the adhesive layer may be attached on the first and second pages 7a′ and 7b′ by means of the adhesive layer and, optionally, the carrier material may be removed after attachment of the metallic foil on the pages 7a′, 7b′, thereby leaving the thin layer of metal on the pages 7a′, 7b′ attached thereto with the adhesive layer. In case that the carrier layer is not removed, the carrier layer may provide an improved bonding strength to subsequently formed layers on the antenna portions 5a′ and 5b′.

With ongoing reference to FIG. 3, the chip module 3′ may further include an integrated circuit chip (not illustrated) and a memory device (not illustrated) which may save personal data of the holder of the document 3, such as identity data of the holder, bank data of the holder, security data of the holder. The memory device (not illustrated) may be only readable or may be readable and writable with new information input by the holder of the document 1′. The integrated circuit chip (not illustrated) may have contact terminals, which may be connected to ends of the first antenna portion 5a′. For example, the first antenna portion 5a′ may be formed by two antenna coil sections (not illustrated), wherein the ends of each of the two antenna coil sections may be connected with a respective one of the contact terminals and with one of the foldable bridges 9a′, 9b′.

In some illustrative embodiments herein, a winding number of the first and second antenna portions 9a′ and 9b′ may be equal.

As described above, the hinge portion 11′ of the document 1′ may be folded such that the first page 7a′ may be folded onto the second page 7b′ or vice versa. In some illustrative embodiments herein, the first and second antenna portions 5a′ and 5b′ may be arranged in the first and second pages 7a′ and 7b′ so as to superimpose in the closed condition of the document 1′. For example, the first and second antenna portions 5a′ and 5b′ may have equal size and shape and folding the first page 7a′ and the second page 7b′ into a stacked arrangement brings the first antenna portion 5a′ and the second antenna portion 5b′ into a congruent superimposition.

In accordance with some illustrative embodiments and with ongoing reference to FIG. 3, document 1′ may be a booklet. In this case, the first and second pages 7a′ and 7b′ may correspond to a booklet cover of the booklet. The booklet may comprise one or more additional pages (not illustrated) connected to the hinge portion 11′, the one or more pages (not illustrated) being enclosed by the booklet cover.

Referring to FIG. 3, the first and second antenna portions 5a′, 5b′ of the document 1′ have a first inductance adapted to provide the document 1′ with a first resonance frequency in the closed condition of the document 1′ in which the first page 7a′ is placed on the second page 7b′, while the first and second antenna portions 5a′, 5b′ have a second inductance adapted to provide the document 1′ with a second resonance frequency different from the first resonance frequency in the open condition of the document in which the first page is removed from the closed condition. In some illustrative embodiments herein, the first and second antenna portions 5a′, 5b′ may be formed with equal winding orientation in the open condition and with opposite winding orientation in the closed condition, while in some other illustrative embodiments, the first and second antenna portions 5a′, 5b′ may be formed with opposite winding orientation in the open condition and with equal winding orientation in the closed condition. In any of these illustrative embodiments, the second resonance frequency may be matched with the resonance frequency of an external reader (not illustrated), while the first resonance frequency may be detuned from the second resonance frequency such that an external reader (not illustrated) is not able to communicate with the chip module 3′ of the document 1′ in the closed condition. For example, the second resonance frequency may be in a range from about 10 MHz to about 15 MHz, preferably in a range from about 11 MHz to about 14 MHz, such as about 13.5 MHz. The first resonance frequency may deviate from the second resonance frequency by at least 5% or at least 10% or at least 20% of the second resonance frequency. For example, the first resonance frequency may be greater than 14 MHz or greater than 15 MHz or greater than 19 MHz, e.g., in a range from about 19 MHz to about 21 MHz.

With ongoing reference to FIG. 3, experiments were performed by the inventors on document 1′, where an external reader (not illustrated), e.g., an SCM reader, is successively positioned at Position 1, Position 2, and Position 3 in the open condition, and is successively positioned at Position 1 and Position 2 in the closed condition. These experiments were performed with the document 1′ in a configuration (configuration A) with equal winding orientation of the first and second antenna portions 5a′ and 5b′, and with the document 1′ in a configuration (configuration B) with opposite winding orientation of the first and second antenna portions 5a′ and 5b′. In both configurations, the RF chip module is a leadframe module comprising an integrated circuit chip with contact terminals. Antenna ends were TC bonded to the contact terminals.

In configuration A, the following reading results were obtained in the open condition:
Position 1: readable
Position 2: unreadable
Position 3: readable

In configuration A, the following reading results were obtained in the closed condition:
Position 1: unreadable
Position 2: unreadable

The frequency responses were measured in the closed condition for configuration A. Results were as follows:
Mold side up:
Position 1: 20.46 MHz
Position 2: 20.73 MHz
Lead frame side up:
Position 1: 20.25 MHz
Position 2: 20.78 MHz

In configuration B, the following reading results were obtained in the open condition:
Position 1: readable
Position 2: unreadable
Position 3: readable

In configuration B, the following reading results were obtained in the closed condition:
Position 1: unreadable
Position 2: unreadable

For configuration B, the frequency responses were measured in the closed condition, with results as follows:
Mold side up:
Position 1: 19.46 MHz
Position 2: 20.46 MHz
Lead frame side up:
Position 1: 20.90 MHz
Position 2: 21.00 MHz

Accordingly, the experiments show that in each of the configurations A and B, a shielding is achieved in the closed condition due to a shift in the resonance frequency sufficiently separated from a resonance frequency of the reader.

1. A document having a first page and a second page connected by a hinge portion, the document comprising:
an RF chip module;
a first antenna portion formed on the first page;
a second antenna portion formed on the second page; and
two foldable bridges crossing the hinge portion, the two foldable bridges being formed by two flexible strip portions of electrically conductive material, each flexible strip portion extending across a fold of the hinge portion,
wherein the one two foldable bridges electrically connects endings of the first and second antenna portions such that the first and second antenna portions have a first inductance adapted to provide the document with a first resonance frequency in a closed condition of the document in which the first page is placed on the second page, while the first and second antenna portions have a second inductance adapted to provide the document with a second resonance frequency different from the first resonance frequency in an open condition of the document in which the first page is not placed on the second page.

2. The document of claim 1, wherein the first and second antenna portions are formed with equal winding orientation in the open condition and with opposite winding orientation in the closed condition.

3. The document of claim 1, wherein the first and second antenna portions are formed with opposite winding orientation in the open condition and with equal winding orientation in the closed condition.

4. (canceled)

5. The document of claim 1, wherein each flexible strip portion is attached to the first and second pages via attachment points provided in the first and second pages and/or each flexible strip portion is attached to wire end portions of the first and second antenna portions.

6. The document of claim 1, wherein the first and second antenna portions are arranged in the first and second pages so as to superimpose in the closed condition.

7. The document of claim 6, wherein the first and second antenna portions have equal size and shape.

8. The document of claim 1, wherein the RF chip module comprises an integrated circuit chip with contact terminals, the contact terminals being connected to ends of one of the first and second antenna portions.

9. The document of claim 8, wherein the first antenna portion is formed by two antenna coil sections, wherein the ends of each of the two antenna coil sections are connected with a respective one of the contact terminals and with the two foldable bridges.

10. The document of claim 1, wherein the RF chip module is integrated on one of the first page and the second page.

11. The document of claim 1, wherein the first and second antenna portions each comprise a conductive material, e.g., aluminum and/or copper and/or silver and/or a metal alloy material and/or a conductive foil laminated with an insulated layer and/or a wire and/or a conductive ink.

12. The document of claim 1, wherein the first and second antenna portions are formed by at least one of a copper wire embedded in the first page and/or the second page, an etched metallic foil disposed over the first page and/or the second page and a conductive ink printed onto the first page and/or the second page.

13. The document of claim 1, wherein the document is a booklet having a booklet cover formed by the first page, the second page, and/or one or more additional pages connected to the hinge portion, the one or more additional pages being enclosed by the booklet cover.
